(19) United States
(12) Patent Application Publication
(10) Pub. No.: US 2008/0119002 A1
(43) Pub. Date: May 22, 2008

(54) Substrate contact for a MEMS device

(76) Inventors: Charles Grosjean, San Jose, CA (US); Paul Merritt Hagelin, Saratoga, CA (US); Nicholas Ian Buchan, San Jose, CA (US)

Correspondence Address: PATTERSON & SHERIDAN, L.L.P., 3040 POST OAK BOULEVARD, SUITE 1500, HOUSTON, TX, 77056, US

(21) Appl. No.: 11/941,056

(22) Filed: Nov. 15, 2007

Related U.S. Application Data
(60) Provisional application No. 60/866,397, filed on Nov. 17, 2006.

(51) Int. Cl. H01L 21/00

(52) U.S. Cl. 438/50; 257/E21.001

(57) ABSTRACT

One embodiment of the present invention sets forth a substrate contact for a MEMS device die, where the substrate contact is formed through an electrically insulative layer in the device die that is positioned between a handle wafer layer and a MEMS device layer formed on the handle wafer layer. The substrate contact serves as a path to ground for the MEMS handle wafer layer and is formed during the fabrication process of the MEMS device. One advantage of the disclosed invention is that a robust, low-impedance path to ground is provided for the MEMS handle wafer layer, with minimal impact on the process of fabricating a MEMS device.

### BACKGROUND OF THE INVENTION

1. Field of the Invention

Embodiments of the present invention relate generally to microelectromechanical system (MEMS) devices, and more specifically to a substrate contact for a MEMS device.

2. Description of the Related Art

For proper operation of a packaged microelectromechanical system (MEMS) device, it is generally advantageous to control the electrical potential of all layers in the MEMS device. Doing so is especially important in electrostatically-actuated devices, such as MEMS resonators, since uncontrolled electric fields can significantly affect the performance of the MEMS device. In this vein, in some MEMS device designs, the MEMS device and the handle wafer layer on which the MEMS device is formed are electrically connected to the electrical ground of an electronics chip configured to control the MEMS device. The low impedance and high reliability of the electrical connections between the MEMS device and electrical ground and between the handle wafer layer and electrical ground are desirable for low feed-through currents and robust device performance.

In some stacked die configurations, a MEMS die is mounted onto a control chip by means of a conductive epoxy, where the back of the MEMS chip is attached to the front of the control chip. Because the MEMS device layer formed on the MEMS die is typically isolated electrically from the handle wafer layer on which the MEMS device layer is formed, a separate ground path is established for the MEMS device layer and for the handle wafer layer. For example, FIG. 1 illustrates a schematic side view of a MEMS chip 100 that contains a MEMS device layer 101 and a handle wafer layer 102 and is mounted on a control chip 103. Wire bond 104 provides a reliable low-impedance electrical connection between MEMS device layer 101 and the electrical ground (not shown) of control chip 103. A buried oxide layer 105 electrically isolates handle wafer layer 102 from MEMS device layer 101, therefore handle wafer layer 102 is also provided an electrical connection to the electrical ground of control chip 103, i.e., via the conductive epoxy layer 106 and one or more contact openings 110 on the top surface of control chip 103. One problem with this type of design is that the use of conductive epoxy layer 106 as a ground path for handle wafer layer 102 is known to form a relatively high-impedance path to ground, e.g., up to several megohms. Consequently, for some MEMS devices, the lowest impedance path between handle wafer layer 102 and ground is the capacitive interface between MEMS device layer 101 and handle wafer layer 102. Such a path results in unwanted feed-through currents. In addition, the use of conductive epoxy layer 106 as a ground path is considered less reliable than other grounding techniques, such as wire bonding. Further, because forming a ground path to contact openings on a control chip with conductive epoxy layer 106 is a non-standard mounting technique, such an approach is considered a reliability risk for the packaging process.

As the foregoing illustrates, there is a need in the art for a direct, low-impedance electrical connection between the handle wafer layer and the MEMS device layer formed on the handle wafer layer that does not substantially impact the reliability of the MEMS device package.

### SUMMARY OF THE INVENTION

One embodiment of the present invention sets forth a substrate contact for a MEMS device die, where the substrate contact is formed through an electrically insulative layer in the device die that is positioned between a handle wafer layer and a MEMS device layer formed on the handle wafer layer. The substrate contact serves as a path to ground for the MEMS handle wafer layer and is formed during the fabrication process of the MEMS device. Embodiments also contemplate methods for forming the substrate contact in conjunction with MEMS device fabrication. One advantage of the disclosed invention is that a robust, low-impedance path to ground is provided for the MEMS handle wafer layer, with minimal impact on the process of fabricating a MEMS device.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates a schematic side view of a MEMS chip that contains a MEMS device layer and a handle wafer layer and is mounted on a control chip, according to the prior art.

FIG. 2 illustrates a partial sectional view of a MEMS chip with a substrate contact disposed between a MEMS device layer and a handle wafer layer, according to one embodiment of the invention.

FIGS. 3A-E illustrate partial schematic side views of a substrate contact being formed, according to one embodiment of the invention.

FIGS. 4A-H illustrate partial schematic side views of a handle wafer, on which substrate contacts are formed simultaneously with a MEMS resonator, according to one embodiment of the invention.

FIGS. 5A-D illustrate partial schematic side views of a handle wafer, on which a substrate contact and MEMS resonator are formed using shared process steps, according to one embodiment of the invention.

FIGS. 6A and 6B are schematic cross-sectional views of a substrate trench after being sealed by the deposition of a seal layer, according to one embodiment of the invention.

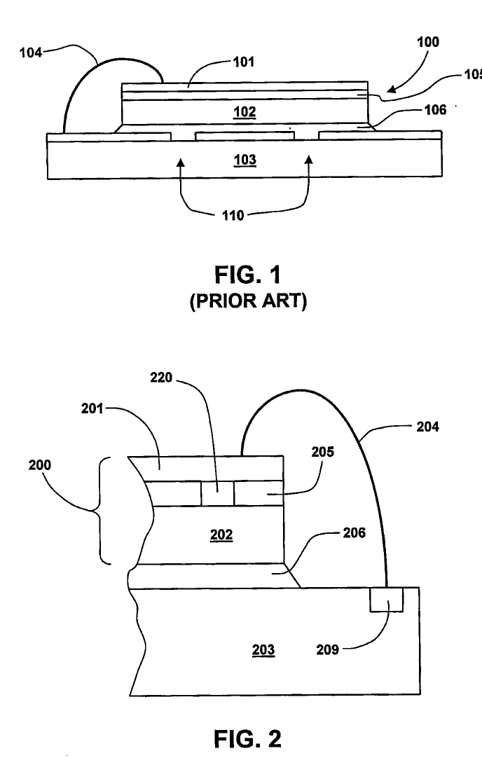

For clarity, identical reference numbers have been used, where applicable, to designate identical elements that are common between figures. It is contemplated that features of one embodiment may be incorporated in other embodiments without further recitation.

### DETAILED DESCRIPTION

Embodiments of the invention set forth a low-impedance electrical interconnect between a MEMS device and the MEMS handle wafer layer on which the MEMS device is formed. The electrical interconnect, or substrate contact, is formed internally through the buried oxide layer insulating the MEMS device layer from the MEMS handle wafer layer, thereby providing a robust, low-impedance path to ground for the MEMS handle wafer layer. In addition, the substrate contact is formed during the fabrication process of the MEMS device, thereby minimizing impact on the fabrication process. In one embodiment, the substrate contact is formed through the buried oxide in process steps prior to the fabrication of the MEMS device. In another embodiment, the substrate contact is formed using the same fabrication steps used to form the MEMS device, where some of the process steps are modified to widen the process window for substrate contact formation. In yet another embodiment, the substrate contact is formed during the fabrication steps of the MEMS device, but additional process steps are used to widen the process window for substrate contact formation.

FIG. 2 illustrates a partial sectional view of a MEMS chip 200 with a substrate contact 220 disposed between a MEMS device layer 201 and a handle wafer layer 202, according to one embodiment of the invention. MEMS device layer 201 contains a MEMS device and is formed on handle wafer layer 202 through a series of process steps known in the art, e.g., deposition, lithography, and etch. Substrate contact 220 penetrates a buried oxide layer 205 that is disposed on handle wafer layer 202 as shown, and is made up of a conductive material, such as single crystal or polycrystalline silicon. As used herein, “conductive” is defined as being sufficiently dissipative of electric charge to prevent a substantial potential difference from developing between MEMS device layer 201 and handle wafer layer 202, i.e., having an impedance of no more that about 1 megohm. MEMS chip 200 is mounted on a control chip 203 by means of an electrically insulative epoxy layer 206. Control chip 203 is an electronic chip, such as a CMOS chip, and is configured to operate and control the MEMS device contained in MEMS chip 200. A wire bond 204 provides an electrical connection for MEMS device layer 201 to an electrical ground 209 of control chip 203. The ground path for handle wafer layer 202 passes through substrate contact 220, into MEMS device layer 201, and through wire bond 204 to electrical ground 209.

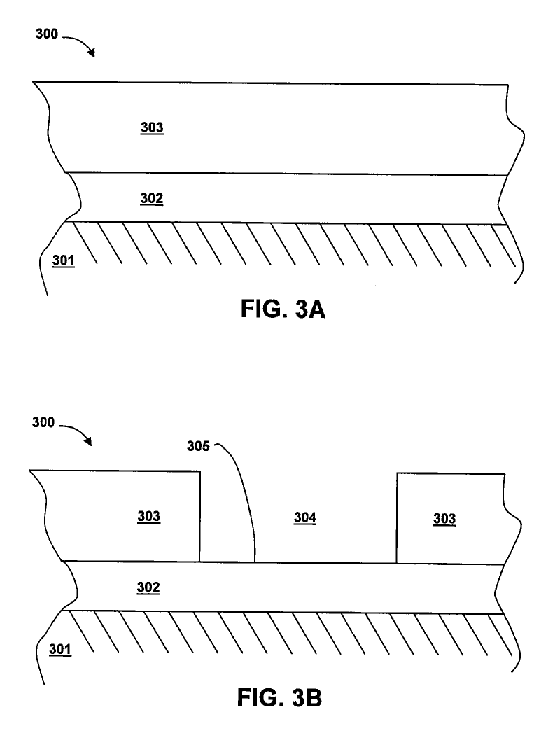

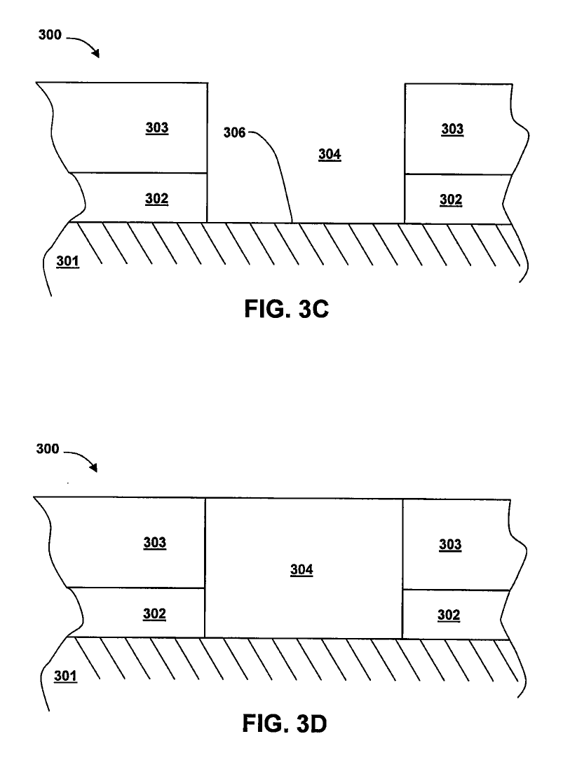

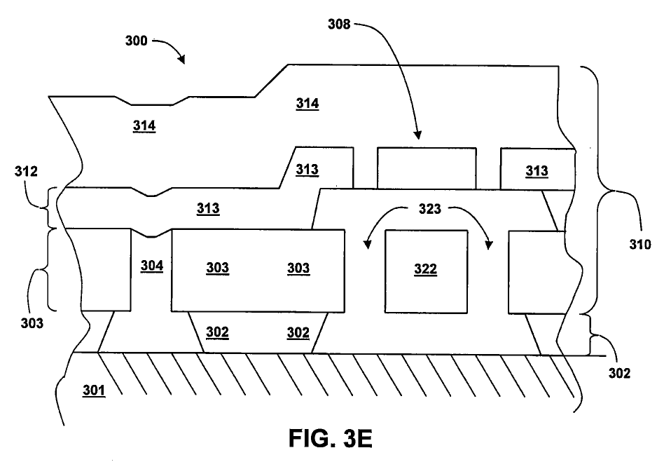

FIGS. 3A-E illustrate one embodiment, in which substrate contact 220 is formed prior to MEMS device layer 201 in the fabrication process. FIG. 3A illustrates a partial schematic side view of a handle wafer 300 prior to the formation of a MEMS device thereon. Handle wafer 300 is a substrate having a handle wafer layer 301, a buried oxide layer 302, and a device layer 303. Handle wafer layer 301 is made up of single crystal silicon, and buried oxide layer 302 is an electrically insulative layer, such as a layer of silicon dioxide (SiO₂), disposed on the top surface thereof. Device layer 303 is also made up of single crystal silicon and is used for the formation of the different components of the subsequently formed MEMS device. In this embodiment, a MEMS device layer 310 substantially similar to MEMS device layer 201 in FIG. 2 is formed on handle wafer layer 301 after a substrate contact 307 has been formed, as shown in FIG. 3E.

FIG. 3B illustrates a partial schematic side view of handle wafer 300 after a substrate contact trench 304 has been formed thereon using lithography and etching processes commonly known in the art. For example, a photo-resist layer may be deposited on the top surface of device layer 303 and exposed to a suitable light source via a standard lithographic process to produce an etch mask (not shown). Then an etch process may be performed on handle wafer 300, such as an ion-etch, in which material is removed from regions of handle wafer 300 not covered by the etch mask, thereby forming substrate contact trench 304 and exposing surface 305 of buried oxide layer 302. In one embodiment, a deep reactive ion etch (DRIE) method is used. The etch mask may then be removed by a standard oxygen asher process.

FIG. 3C illustrates a partial schematic side view of handle wafer 300 after substrate contact trench 304 has been extended to surface 306 of handle wafer layer 301 by removing a portion of buried oxide layer 302 as shown. The portion of buried oxide layer 302 may be removed by a dedicated oxide etch process, such as an HF-based vapor- or wet-etch process, to expose surface 306. Alternatively, the portion of buried oxide layer 302 exposed to contact trench 304 may be removed by a continuation of the etching process used to remove material from device layer 303, as shown in FIG. 3B.

FIG. 3D illustrates a partial schematic side view of handle wafer 300 after substrate contact trench 300 has been filled with a conductive material to form substrate contact 307. The conductive material used to form substrate contact 304 is single crystal or polycrystalline silicon grown from the bottom surface 306 of substrate contact trench 304. In one embodiment, a dedicated silicon deposition process is used to fill substrate contact trench 304, such as an epitaxial silicon process. In this embodiment, MEMS device layer 310 is then formed on handle wafer 300 and substrate contact 304, as shown in FIG. 3E. Alternatively, substrate contact trench 304 may be filled with a silicon-based conductive material by a subsequent deposition step that is also used to form MEMS device layer 310.

FIG. 3E illustrates a partial schematic side view of handle wafer 300 and substrate contact 304 after MEMS device layer 310 has been formed thereon. MEMS device layer 310 includes a device layer 303, a trench fill oxide layer 312, a vent layer 313, and a seal layer 314. Device layer 303 is a single-crystal silicon layer in this embodiment that may range in thickness between about 5 μm and about 20 μm. Components of a MEMS resonator 308, e.g., a resonator beam 322, a sense electrode (not shown), a drive electrode (not shown), etc., are defined in device layer 303 by the formation of trenches 323 in device layer 303. Trench fill oxide layer 312 is a conventional silicon dioxide (SiO₂) layer and may range in thickness from about 0.5 μm to 2.0 μm. Vent layer 313 is a conductive, silicon-based material, such as polysilicon, and may range in thickness between about 1 μm to 4 μm in thickness, or more. Seal layer 314 is a polysilicon layer that is 10-50 μm or more in thickness forming a mechanically robust membrane that can withstand the stresses of fabrication, manufacturing, and packaging of handle wafer 300 and MEMS device 308. The formation of MEMS resonator 308 and MEMS device layer 310 is described in greater detail below in conjunction with other embodiments of the invention.

One advantage of the embodiment illustrated in FIGS. 3A-E is the formation of a robust electrical connection between the handle wafer layer and the MEMS device layer of a MEMS chip. As described above, the connection is formed by a substrate contact filled with a conductive material and firmly contacting the handle wafer layer and the MEMS device layer of a MEMS chip. In addition, the substrate contact is formed by a process having a large process window. To with, each step in the process of forming the substrate contact, i.e., trench formation, oxide removal, and trench fill, is performed with a dedicated process, which can be optimized according to the geometry of the substrate contact and is not affected by the geometry of other features of the MEMS chip. Further, because the substrate contact is formed inside the MEMS chip and does not rely on a conductive epoxy, the packaging process for the MEMS chip is more reliable. Yet another advantage is the added protection against stiction of MEMS device components against adjacent surfaces that can occur during the fabrication process. Because the substrate contact is formed prior to the release of any movable MEMS components, little or no potential difference between the MEMS device layer and the handle wafer is generated during fabrication of the MEMS device, thereby substantially eliminating the possibility of stiction occurring.

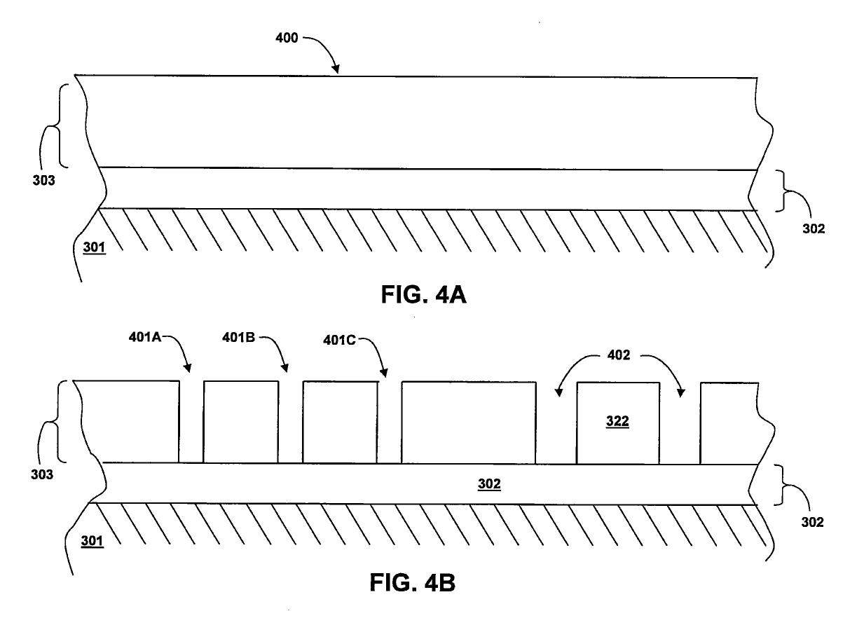

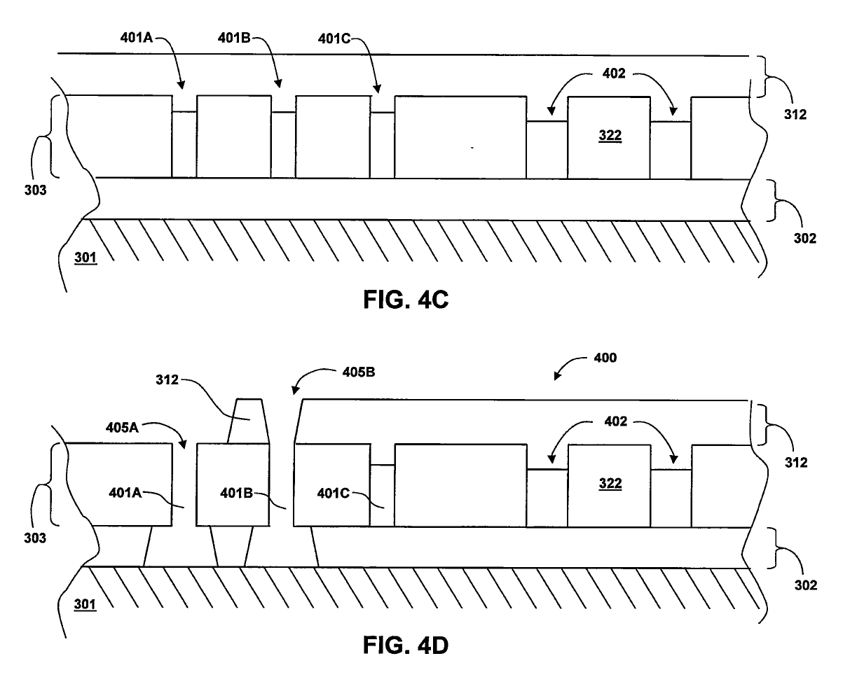

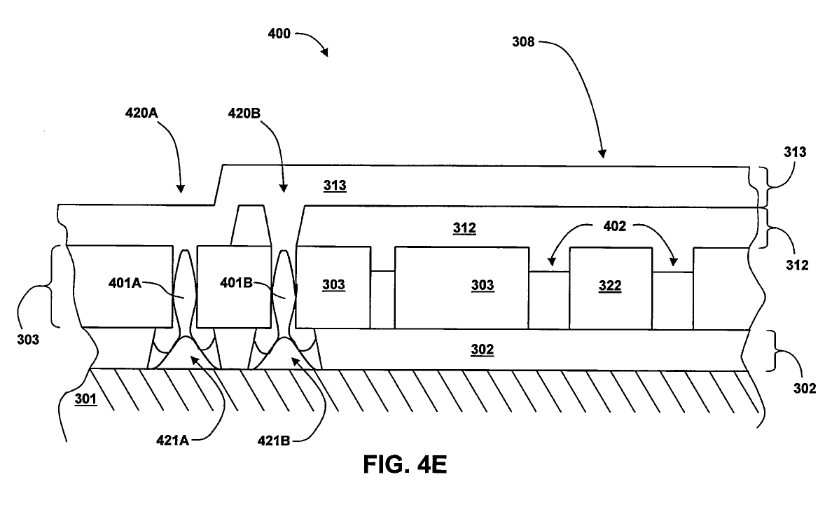

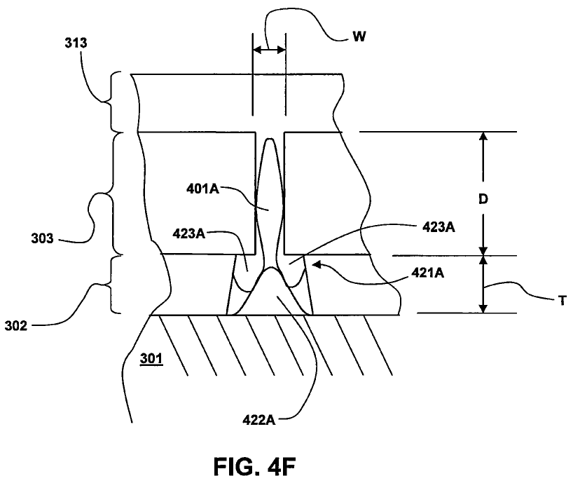

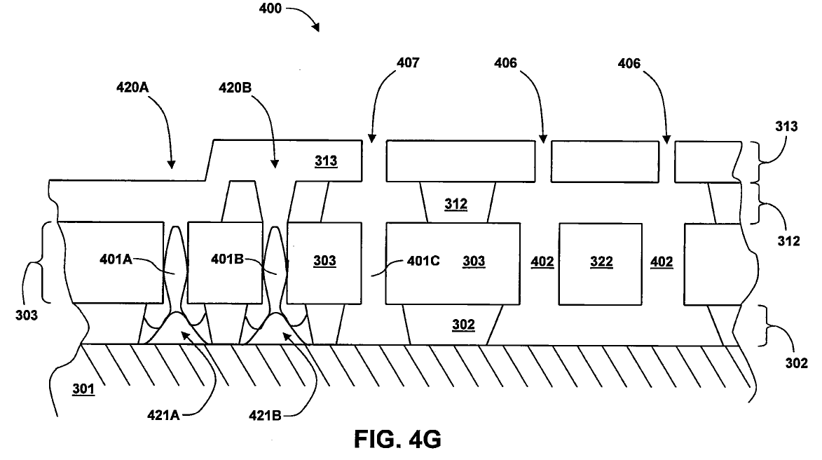

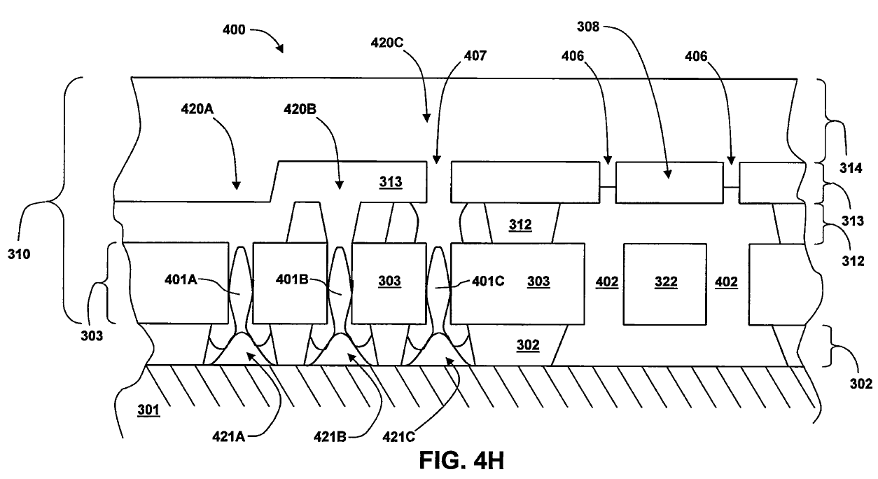

According to another embodiment, a substrate contact, such as substrate contact 220 in FIG. 2, is formed on a handle wafer using the same fabrication steps used to form a MEMS device on the handle wafer, thereby minimizing the impact on the overall fabrication process of the MEMS device. In this embodiment, some MEMS device fabrication steps may be modified to optimize the process window for substrate contact formation. FIGS. 4A-H illustrate partial schematic side views of a handle wafer 400, on which three substrate contacts 420A-C are formed simultaneously with a MEMS resonator 308, in accordance with embodiments of the invention. Each of substrate contacts 420A-C illustrates a different device structure in which a substrate contact is formed using the same process sequence steps used to fabricate MEMS resonator 308. Handle wafer 400 is similar in configuration to handle wafer 300 illustrated in FIGS. 3A-E, and identical reference numbers have been used, where applicable, to designate the common elements between these two embodiments. Handle wafer 400 is a substrate having handle wafer layer 301, buried oxide layer 302, and device layer 303. For clarity, no isolation trench is illustrated insulating the substrate contacts 420A-C formed on handle wafer 400 from the components of MEMS resonator 308 formed on handle wafer 400.

FIG. 4A illustrates a partial schematic side view of handle wafer 400 prior to the formation of a MEMS device or substrate contacts thereon. FIG. 4B illustrates a partial schematic side view of handle wafer 400 after the formation of substrate contact trenches 401A-C and resonator trenches 402 in device layer 303.

In one embodiment, substrate contact trenches 401A-C and resonator trenches 402 are formed during the same silicon etch process, such as a DRIE process. FIG. 4C illustrates handle wafer 400 after the deposition of trench fill oxide layer 312, which may be formed by a PECVD TEOS method, a PECVD silane method, or an LPCVD method, among others. As shown, trench fill oxide layer 312 is deposited as a blanket layer covering the entire upper surface of handle wafer 400.

FIG. 4D illustrates handle wafer 400 after patterning and etching of trench fill oxide layer 312, using lithographic and etching methods commonly used in the art, such as an HF-based vapor- or wet-etch. As shown, trench fill oxide layer 312 is completely removed from the region adjacent aperture 405A of substrate contact trench 401A and is left in place around the opening of substrate contact trench 401B, forming an aperture 405B aligned with substrate contact trench 401B. Trench fill oxide layer 312 over substrate contact trench 401C and resonator trenches 402 is masked during the oxide etch process and is left substantially intact. The etching process used to remove the material of trench fill oxide layer 312 is also used to remove a portion of buried oxide layer 302 disposed at the bottom of substrate contact trenches 401A and 401B, thereby exposing handle wafer layer 301.

FIG. 4E illustrates handle wafer 400 after deposition of vent layer 313, which is formed by epitaxial silicon deposition methods commonly used in the art. Because substrate contact trenches 401A and 401B are open prior to the formation of vent layer 313, the epitaxial deposition process used to form vent layer 313 also deposits a silicon-based conductive material at the bottom of contact trenches 401A and 401B to form electrical connections 421A, 421B between handle wafer layer 301 and device layer 303. FIG. 4F illustrates a schematic side view of electrical connection 421A formed at the bottom of substrate contact trench 401A. Electrical connection 421A is produced when a region of bottom silicon growth 422A contacts regions of sidewall growth 423A. To prevent the deposition of vent layer 313 from closing off apertures 405A, 405B before electrical connections 421A, 421B are formed, the epitaxial silicon deposition process may be modified as desired. Factors affecting the epitaxial silicon deposition process include the depth D and width W of substrate contact trenches 401A and 401B and the thickness T of buried oxide layer 302. One skilled in the art, upon reading the disclosure herein, can modify an epitaxial silicon deposition process as desired to form electrical connections 421A, 421B in substrate contact trenches 401A, 401B, respectively. In this way, substrate contacts 420A, 420B can be formed on handle wafer 400 simultaneously with MEMS resonator 308 with no additional process steps.

FIG. 4G illustrates handle wafer 400 after vents 406, 407 are etched in vent layer 313 and after an HF release process, such as a vapor- or wet-etch process, has been performed on handle wafer 400. Vents 406, 407 are formed in vent layer 313 via standard lithographic and silicon etch processes commonly used in the art. Vents 406 are formed in vent layer 313 proximate resonator trenches 402 so that the subsequent HF release process removes portions of trench fill oxide layer 312 and buried oxide layer 302, as shown. In this way, the HF release process releases resonator beam 322 and separates resonator beam 322 from sense electrode 320 and drive electrode 321. Similarly, vent 407 is formed over substrate contact trench 401C so that the HF release process removes a portion of buried oxide layer 302 disposed at the bottom of substrate contact trench 401C, thereby exposing handle wafer layer 301. The embodiments illustrated by substrate contacts 420A, 420B are masked during the vent etch and HF release etch processes.

FIG. 4H illustrates handle wafer 400 after seal layer 314 has been deposited onto handle wafer 400 by epitaxial silicon deposition methods commonly used in the art. Because substrate contact trench 401C is open via vent 407 prior to the deposition of seal layer 314, the epitaxial deposition process used to form vent layer 314 also deposits a silicon-based conductive material at the bottom of contact trench 401C. This conductive material forms electrical connection 421C between handle wafer layer 301 and device layer 303 in the same manner describe above for electrical connections 421A, 421B. To prevent the deposition of seal layer 314 from closing off vent 407 before electrical connection 421C is formed, the epitaxial silicon deposition process may be modified as desired. Factors affecting the epitaxial silicon deposition process include the depth D and width W of substrate contact trench 401C and the thickness T of buried oxide layer 302, where depth D, width W, and thickness T are depicted in FIG. 4F for substrate contact 401A. One skilled in the art, upon reading the disclosure herein, can modify an epitaxial silicon deposition process as desired to form electrical connections 421C in substrate contact trench 401C. Thus, substrate contact 420C is formed, providing a low-impedance path between handle wafer layer 301 and device layer 303, using the same sequence of process steps for forming MEMS resonator 308. In the embodiment illustrated in FIG. 4H, the impedance of the ground path between handle wafer layer 301 and device layer 303 may approximately 100 kilohm.

An advantage of the embodiments illustrated by substrate contacts 420A-C in FIGS. 4A-4H is that no additional process steps, e.g., lithography, etching, or deposition, are required to form a low-impedance electrical connection between handle wafer layer 301 and device layer 303. Consequently, the process of fabricating MEMS resonator 308 on handle wafer 400 may be completed with minimal modification. In addition, the formation of substrate contacts 420A-C, as described herein, provides protection against stiction of MEMS device components against adjacent surfaces that can occur during the fabrication process. Because the substrate contact is formed immediately after the release of any movable MEMS components, there is very little opportunity for an electrostatic potential difference to develop between the MEMS device layer and the handle wafer. Finally, implementation of one of substrate contacts 420A-C simplifies the packaging process, thereby reducing cost and increasing reliability.

In yet another embodiment, a substrate contact and a MEMS device layer, such as substrate contact 220 and MEMS device layer 201 in FIG. 2, are formed on a handle wafer, where most of the process steps used to form the MEMS device are also used to form the substrate contact. In this embodiment, a limited number of additional process steps are also used to complete the formation of the substrate contact. The additional process steps are included in the process sequence to optimize the process window for the formation of the substrate contact and the MEMS resonator. In this way, the addition of a substrate contact to the configuration of the MEMS device is completed with a relatively large process window and minimal impact on the overall fabrication process of the MEMS device.

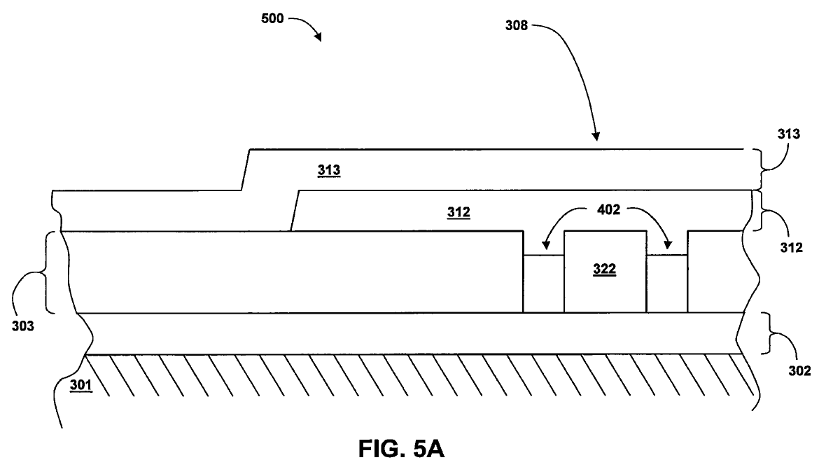

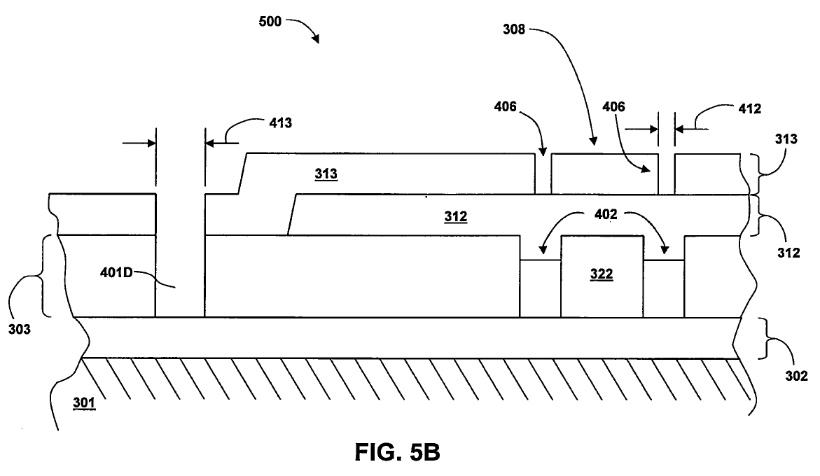

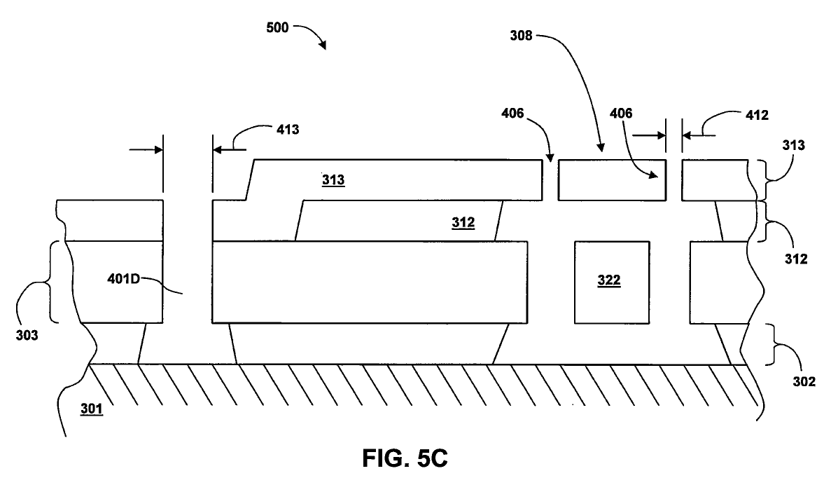

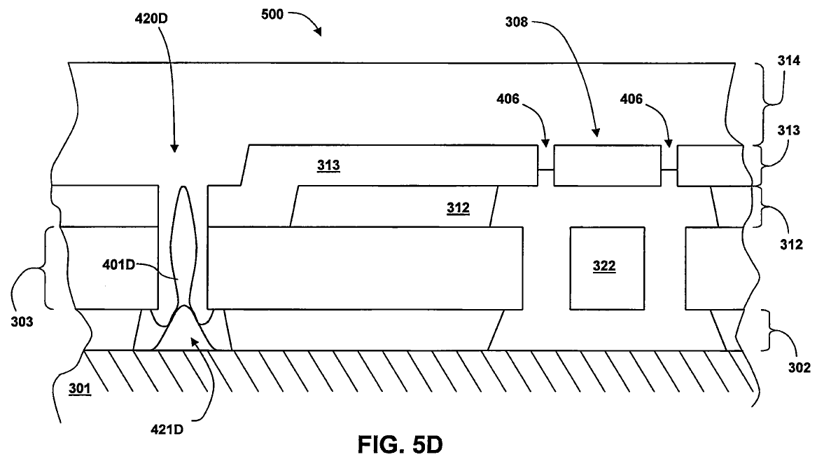

FIGS. 5A-D illustrate partial schematic side views of a handle wafer 500, on which a substrate contact 520 and MEMS resonator 308 are formed using shared process steps, according to one embodiment of the invention. Handle wafer 500 is similar in configuration to handle wafer 400 illustrated in FIGS. 4A-H, and identical reference numbers have been used, where applicable, to designate the common elements between these two embodiments. For clarity, no isolation trench is illustrated insulating the substrate contact 520 formed on handle wafer 500 from the components of MEMS resonator 308 formed on handle wafer 500.

FIG. 5A illustrates handle wafer 500 after several process steps in the formation of MEMS resonator 308 have been performed, including: the formation of resonator trenches 402 in device layer 303; the deposition, patterning, and etching of trench fill oxide layer 312; and the deposition of vent layer 313. As shown, no substrate contact trench has yet been formed in device layer 303 and resonator trenches 402 are covered by trench fill oxide layer 312 and vent layer 313.

FIG. 5B illustrates handle wafer 500 after the formation of substrate trench 401D in device layer 303 and vents 406 are formed in vent layer 313. Substrate trench 401D and vents 406 are formed using standard lithography and silicon-etching processes known in the art. In one embodiment, a hardmask (not shown), such as an SiO₂ hard mask, is deposited and patterned on the surface of handle wafer 500 to define substrate trench 401D and vents 406, and a DRIE process is used to form substrate trench 401D and vents 406. In this embodiment, the DRIE process may be an optimized etch process to allow the formation of substrate trench 401D, while preventing the over-etching of vents 406. The DRIE process optimization may be necessary when the depth of substrate trench 401D is significantly larger than the depth of vent 406, e.g., when the thickness of device layer 303 is approximately an order of magnitude greater than the thickness of vent layer 313.

In another embodiment, vents 406 and a portion of substrate trench 401D are formed in vent layer 313 in a silicon-etch process as described above, and the remaining portion of substrate trench 401D is formed through device layer 303 via additional masking and etching steps. In this embodiment, an additional masking step is performed on handle wafer 500 to cover vents 406 with photoresist or other patterned masking material, and the remainder of substrate trench 401D is formed via a dedicated silicon etching process, such as a DRIE process. This embodiment is particularly useful when there is a substantial disparity between the width 412 of vents 406 and the width 413 of substrate trench 401D, e.g., when width 412 is about 0.4 μm or less and width 413 is about 2 μm or more. Similarly, this embodiment is useful when the thickness of device layer 303 is approximately an order of magnitude greater than the thickness of vent layer 313.

In still another embodiment, vents 406 are formed in a first silicon etch process, and substrate contact trench 401D is formed in a second silicon etch process. In this embodiment, a first mask, such as an SiO₂ hardmask, is patterned and etched to define the locations of vents 406 and optionally substrate contact trench 401D. At this time, a silicon etch process is used to etch the vents. A second mask, such as a photoresist mask, is then formed over the hardmask, exposing the opening for substrate contact trench 401D while protecting the already defined vent holes. If necessary, an oxide etch process is used to first open holes in the remaining oxide hardmask. Then, a silicon-etch process, such as a DRIE process tuned for producing a relatively large diameter, deep trench, is performed on handle wafer 500 to form substrate contact trench 401D. The second mask is then stripped. Finally, the first mask is removed. When the first mask is an SiO₂ hardmask, removal of said hardmask may take place in the HF release process described below in conjunction with FIG. 5C. This embodiment is useful when the quality of the size and shape of vents 406 is an important consideration in the fabrication of MEMS device 308 and allows a more aggressive etching step to be used to form substrate contact trench 401D. In this way, the desired size and shape of vents 406 is not distorted by the prolonged etching step generally used to form wider, deeper features like substrate contact trench 401D. Other etching and masking schemes using different masking layers and removal of said masks at different times are also contemplated, and one skilled in the art, upon reading the disclosure contained herein, can readily devise such etching and masking schemes.

FIG. 5C illustrates handle wafer 500 after an HF release process, such as a vapor- or wet-etch process, has been performed on handle wafer 500. The HF release process removes portions of trench fill oxide layer 312 and buried oxide layer 302 to release resonator beam 322 in the manner described above in conjunction with FIG. 4G. Similarly, the HF release process removes a portion of buried oxide layer 302 disposed at the bottom of substrate contact trench 401D, thereby exposing a portion of handle wafer layer 301.

FIG. 5D illustrates handle wafer 500 after seal layer 314 has been deposited onto handle wafer 500 by epitaxial silicon deposition methods commonly used in the art. Because substrate contact trench 401D is open prior to the deposition of seal layer 314, the epitaxial deposition process used to form seal layer 314 also deposits a silicon-based conductive material at the bottom of substrate contact trench 401D, in the manner described above for contact trenches 401A and 401B. Said conductive material forms electrical connection 421D between handle wafer layer 301 and device layer 303 in the same manner described above for electrical connections 421A, 421B and illustrated in FIG. 4F, thereby forming substrate contact 420D.

To prevent the deposition of seal layer 314 from closing off vent 406 before electrical connection 421D is formed, the epitaxial silicon deposition process may be modified as desired. Factors affecting how the epitaxial silicon deposition process is optimized to form substrate contact 420D include the depth D and width 413 of substrate contact trench 401D and the thickness T of buried oxide layer 302, where depth D and thickness T are depicted in FIG. 4F and width 413 is depicted in FIG. 5C. For example, when buried oxide layer 302 is greater than about 0.5 μm in thickness, the epitaxial silicon deposition process can be modified to maximize bottom-fill deposition and minimize conformal and sidewall deposition. In so doing, formation of an electrical connection between handle wafer layer 301 and device layer 303 is better ensured. In another example, when width W of substrate contact trench 401D is greater than about 1.5 μm, the epitaxial silicon deposition process can be modified to maximize sidewall deposition and minimize conformal bottom-fill deposition. In such a case, the optimized deposition process reduces the width and depth of depressions, cavities, trenches, or other unwanted topography that may be formed as an artifact of sealing substrate contact trench 401D when said trench is a relatively wide feature. In yet another example, the epitaxial silicon deposition process may include two steps: 1) a sealing step, in which the silicon deposition process is optimized to seal vents 406 quickly while minimizing the deposition of silicon material beneath the vent holes, and 2) a filling step, in which the silicon deposition process is optimized to fill features on a substrate from the bottom up while minimizing sidewall deposition. One skilled in the art, upon reading the disclosure herein, may modify an epitaxial silicon deposition process, as desired, to form electrical connection 421D in substrate contact trench 401D before the opening of substrate contact trench 401D is sealed. Thus, substrate contact 420D is formed, providing a low-impedance path between handle wafer layer 301 and device layer 303.

The device structures illustrated in FIG. 5A-D allow the formation of a substrate contact and a MEMS device by using a number of shared process steps during fabrication. Because substrate contact formation is incorporated into the process flow for creating the MEMS device, the addition of a substrate contact has little impact on the MEMS device fabrication process. Dedicated mask and etch processes for substrate trench formation provide a large process window for both the formation of the relatively small vents used for HF release and the relatively large trench used for the substrate contact. As noted above, this embodiment is particularly useful when there is a substantial disparity in the geometries of the HF release vents and the substrate contact trench.

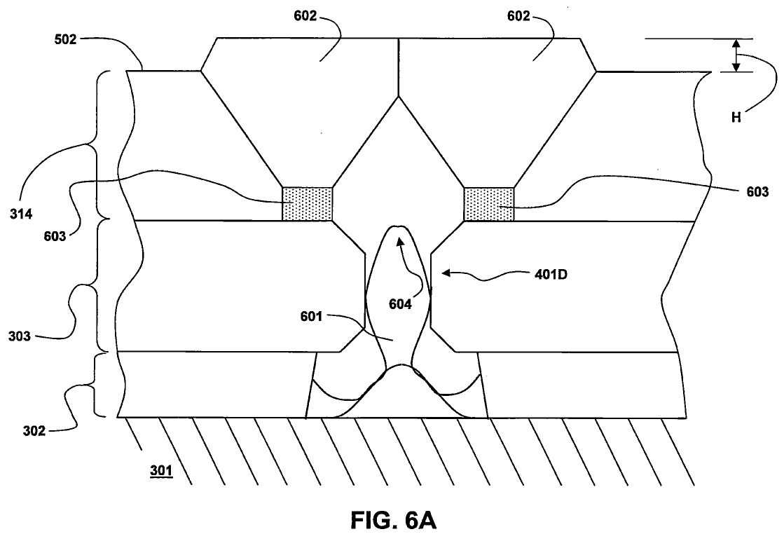

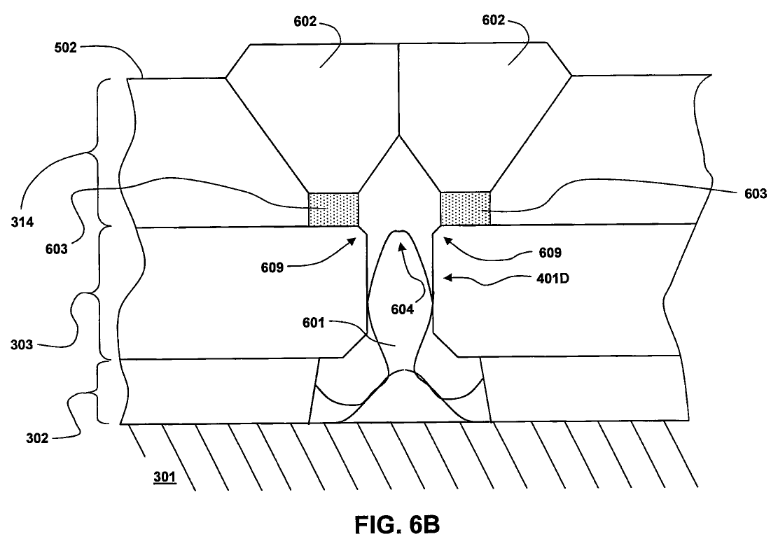

In one embodiment, the formation of unwanted topography may be minimized on the surface 502 of handle wafer 500 after the deposition of seal layer 314. For example, when the width 413 of substrate trench 401D is on the order of 2 μm or greater, a relatively deep cavity may be formed (not shown) on surface 502 as an artifact of the substantially conformal deposition process. Such a cavity or depression is positioned over substrate contact trench 401D, making adequate planarization of surface 502 problematic by necessitating the removal of an excessive thickness of material therefrom. In this embodiment, regions of polysilicon overgrowth are used to seal contact trench 401D, as detailed below in FIGS. 6A, 6B. In terms of planarization of seal layer 314, regions of polysilicon overgrowth are preferable to a cavity on surface 502.

FIG. 6A is a schematic cross-sectional view of substrate trench 401D after being sealed by the deposition of seal layer 314, according to one embodiment of the invention. Keyhole region 601 is sealed by polysilicon overgrowth regions 602, as shown. Oxide regions 603 are disposed on device layer 303 and proximate the opening 604 of substrate contact trench 401D, so that the epitaxial deposition process that forms seal layer 314 on vent layer 313 forms faster-growing regions of polysilicon overgrowth 605 on oxide regions 603. Oxide regions 603 may be portions of trench fill oxide layer 312, as illustrated in FIGS. 5A-C, that have been left in place during previous patterning and etching steps. A small projection of polysilicon of height H is formed over substrate contact trench 401D rather than a dip or cavity. Thus, to planarize surface 502, only a small volume of polysilicon overgrowth is removed instead of the relatively large volume of single-crystal silicon that is removed to planarize a cavity. The advantages of positioning oxide regions 603, as shown in FIG. 6A, are twofold: 1) the faster-growing polysilicon overgrowth regions 602 can seal keyhole region 601 sooner and more reliably than the more conformal growth of single-crystal silicon on device layer 303, and 2) the resultant topography of polysilicon overgrowth regions 602 is substantially easier to planarize than a relatively deep cavity.

In one embodiment, oxide regions 603 are positioned substantially at the edge of opening 604 of contact trench 401D to further improve the sealing of keyhole region 601, as illustrated in FIG. 6B. FIG. 6B is a schematic cross-sectional view of substrate contact trench 401D after being sealed by the deposition of seal layer 314, according to an embodiment of the invention. By positioning oxide regions 603 as near as practicable to the edge of substrate contact trench 401D, surface diffusion of corner regions 609 of substrate contact trench 401D is minimized during the deposition of seal layer 314. In this way, substrate contact trench 401D maintains sharper corner regions 609, the effective width of opening 604 is minimized prior to the deposition of seal layer 314, and is therefore sealed more easily by polysilicon overgrowth regions 602. In this embodiment, vent layer 313 may be deposited on surfaces of oxide regions 602 to beneficially enhance the geometry of opening 604 for subsequent sealing by polysilicon overgrowth regions 602.

The growth rate of silicon on a substrate contact trench sidewall is known to be a function of the orientation of the surface of the sidewall to the crystalline structure of the single crystal silicon making up said sidewall. Embodiments of the invention further contemplate optimizing the orientation of a substrate contact trench with respect to the single crystal silicon that makes up the device layer in which the substrate contact trench is formed. In so doing, sidewall growth of silicon inside the substrate contact trench is minimized during deposition of the material that forms the electrical connection between the device layer and the handle wafer layer. Minimizing sidewall growth of silicon expands the process window for the depositing conductive material, i.e., silicon, between a device layer and a handle wafer layer at the bottom of substrate contact trench, since said trench remains open longer during the deposition process. It is believed that orienting the substrate contact to be “off-angle” with respect to a plane of the crystalline lattice of device layer 303, i.e., neither parallel nor perpendicular thereto, sidewall growth is substantially reduced. For example, referring to FIG. 6A, by orienting substrate contact trench 401D at an off-angle relative to the top, i.e., notch, of a <110> single crystal silicon-on-insulator (SOI) wafer, sidewall growth on device layer 303 inside substrate contact trench 401D can be reduced. Hence, more silicon can be deposited at the bottom of substrate contact trench 401D before opening 604 is closed, thereby producing a more robust electrical connection between device layer 303 and handle wafer layer 301.

While the foregoing is directed to embodiments of the present invention, other and further embodiments of the invention may be devised without departing from the basic scope thereof, and the scope thereof is determined by the claims that follow.

We claim:

1. A method of forming a conductive path between a substrate and a microelectromechanical system (MEMS) device layer formed on the substrate, the method comprising:
providing a substrate with an electrically insulative layer disposed thereon;
depositing one or more layers of the MEMS device layer on the electrically insulative layer;
forming a first trench in the one or more layers of the MEMS device layer in a first region of the MEMS device layer to expose a portion of the electrically insulative layer, wherein the first region does not contain any MEMS devices;
forming a second trench in the one or more layers of the MEMS device layer in a second region of the MEMS device layer after the step of forming the first trench, wherein the second region contains a MEMS device;
forming an opening in the exposed portion of the electrically insulative layer; and
depositing a conductive material in the opening to form a conductive path between the substrate and the MEMS device layer.

2. The method of claim 1, wherein the step of depositing the conductive material comprises depositing a silicon-containing material.

3. The method of claim 3, wherein the step of depositing the conductive material comprises depositing the conductive material via an epitaxial silicon deposition process.

4. The method of claim 1, wherein at least a portion of the conductive path is disposed in the first trench.

5. The method of claim 1, wherein the step of forming the opening comprises removing a portion of the electrically insulative layer to expose a surface of the substrate.

6. The method of claim 5, wherein the exposed surface of the substrate is an electrically conductive surface.

7. The method of claim 5, wherein the step of removing the portion of the electrically insulative layer comprises performing a hydrofluoric acid-based etching process on the portion of the electrically insulative layer.

8. The method of claim 1, further comprising the step of depositing a trench fill layer on the one or more layers of the MEMS device layer.

9. The method of claim 8, wherein the trench fill layer is a silicon dioxide (SiO₂) layer, the second trench comprises a vent hole exposing a portion of the trench fill layer, and the step of removing the portion of the electrically insulative layer comprises removing the exposed portion of the trench fill layer to release a portion of a MEMS resonator device contained in the MEMS device layer.

10. The method of claim 9, wherein the step of depositing the conductive material further comprises simultaneously depositing the conductive material in the second trench.

11. The method of claim 10, wherein the step of depositing the conductive material further comprises:
a sealing step optimized to seal the second trench; and
a filling step optimized to maximize deposition of the conductive material on the exposed surface of the substrate.

12. The method of claim 11, wherein the sealing step is performed before the filling step.

13. The method of claim 1, wherein the step of depositing the conductive material in the opening comprises simultaneously depositing the conductive material to form a conductive layer contained in the MEMS device layer.

14. The method of claim 13, wherein the conductive layer contained in the MEMS device layer comprises a seal layer.

15. The method of claim 1, further comprising the step of forming a third trench in the first region of the MEMS device layer, wherein the step of forming the third trench is performed before the step of forming the first trench.

16. The method of claim 15, wherein step of forming the third trench comprises forming a resonator trench configured to define a resonator beam for a MEMS resonator.

17. The method of claim 16, further comprising the step of depositing a vent layer having a thickness between about 1 μm to 4 μm, wherein the step of forming the third trench comprises etching the resonator trench to define the resonator beam to be between about 5 μm and about 20 μm.

18. The method of claim 1, wherein the step of forming the first trench comprises a deep reactive ion etch (DRIE) process.

19. The method of claim 1, wherein the step of depositing a conductive material comprises depositing a material having an impedance of no more than about 1 megohm.

20. The method of claim 1, wherein electrically insulative layer comprises a silicon dioxide (SiO₂) layer.

21. The method of claim 20, wherein the SiO₂ layer has a thickness of at least about 0.5 μm.
